(19) United States
(12) Patent Application Publication
(10) Pub. No.: US 2010/0247923 A1
(43) Pub. Date: Sep. 30, 2010

(54) ELECTRICALLY CONDUCTIVE POLYMER COMPOSITIONS AND FILMS MADE THEREFROM

(75) Inventor: Che-Hsiung Hsu, Wilmington, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I. DU PONT DE NEMOURS AND COMPANY, Wilmington, DE (US)

(21) Appl. No.: 12/406,172

(22) Filed: Mar. 18, 2009

Related U.S. Application Data
(60) Provisional application No. 61/037,758, filed on Mar. 19, 2008.

(51) Int. Cl. H01B 1/08; B32B 27/06; H01G 9/042

(52) U.S. Cl. 428/419; 252/519.33; 252/519.1; 977/773; 977/932; 977/742; 977/753; 361/532

(57) ABSTRACT

The present invention relates to electrically conductive polymer compositions, and their use in electronic devices. The compositions are an aqueous dispersion including: (i) at least one electrically conductive polymer doped with a non-fluorinated polymeric acid; (ii) at least one highly-fluorinated acid polymer; (iii) at least one high-boiling polar organic solvent, and (iv) nanoparticles of at least one semiconductive metal oxide. The composition may further include an additive which can be one or more of fullerenes, carbon nanotubes, or combinations thereof.

### RELATED APPLICATION

This application claims priority under 35 U.S.C. §119(e) from U.S. Provisional Application No. 61/037,758 filed on Mar. 19, 2008, which is incorporated by reference in its entirety.

### BACKGROUND INFORMATION

1. Field of the Disclosure

This disclosure relates in general to aqueous dispersions of electrically conductive polymers containing solvent and additives, and their use in electronic devices.

2. Description of the Related Art

Electronic devices define a category of products that include an active layer. Organic electronic devices have at least one organic active layer. Such devices convert electrical energy into radiation such as light emitting diodes, detect signals through electronic processes, convert radiation into electrical energy, such as photovoltaic cells, or include one or more organic semiconductor layers.

Organic light-emitting diodes (OLEDs) are an organic electronic device comprising an organic layer capable of electroluminescence. OLEDs containing conducting polymers can have the following configuration:
anode/buffer layer/EL material/cathode
   with additional layers between the electrodes. The anode is typically any material that has the ability to inject holes into the EL material, such as, for example, indium/tin oxide (ITO). The anode is optionally supported on a glass or plastic substrate. EL materials include fluorescent compounds, fluorescent and phosphorescent metal complexes, conjugated polymers, and mixtures thereof. The cathode is typically any material (such as, e.g., Ca or Ba) that has the ability to inject electrons into the EL material. Electrically conducting polymers having low conductivity in the range of 10⁻³ to 10⁻⁷ S/cm are commonly used as the buffer layer in direct contact with an electrically conductive, inorganic oxide anode such as ITO.

Electrically conducting polymers which have the ability to carry a high current when subjected to a low electrical voltage, may have utility as electrodes for electronic devices. However, many conductive polymers have conductivities which are too low for use as electrodes such as the anode for OLEDs. Moreover, they generally have a work-function that is too low for effective hole injection as an anode. Having high conductivity and high work-function is also useful as cathode, for example, in Tantalum/Ta2O5 or Aluminum/Al2O3 capacitors. Furthermore, the mechanical strength of films made from the polymers, either self-standing or on a substrate, may not be sufficient for the electrode applications. In addition, the refractive index of these materials is generally low.

Accordingly, there is a continuing need for improved organic conductive materials.

### SUMMARY

There is provided an aqueous dispersion comprising: (i) at least one electrically conductive polymer doped with at least one non-fluorinated acid polymer; (ii) at least one fluorinated acid polymer; (iii) at least one high-boiling polar organic solvent; and (iv) nanoparticles of at least one semiconductive metal oxide.

In another embodiment, the dispersion further comprises an additive selected from the group consisting of carbon nanotubes, fullerenes, and combinations thereof.

In another embodiment, there is provided a film formed from the above dispersion.

In another embodiment, electronic devices comprising at least one layer comprising the above film are provided.

### BRIEF DESCRIPTION OF THE DRAWING

The invention is illustrated by way of example and not limitation in the accompanying figures.

FIG. 1 is a schematic diagram of an organic electronic device.

Skilled artisans will appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

There is provided an aqueous dispersion comprising: (i) at least one electrically conductive polymer doped with at least one non-fluorinated polymeric acid; (ii) at least one fluorinated acid polymer; (iii) at least one high-boiling polar organic solvent, and (iv) nanoparticles of at least one semiconductive metal oxide. The above dispersion is referred to herein as the “new composition” and the “composite dispersion”.

Many aspects and embodiments are described herein and are merely exemplary and not limiting. After reading this specification, skilled artisans will appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Doped Electrically Conductive Polymer, the Highly-Fluorinated Acid Polymer, the Solvent, the Nanoparticles of Semiconductive Metal Oxide, Other Additives, Preparation of the Doped Electrically Conductive Polymer Composition, Buffer Layers, Electronic Devices, and finally, Examples.

### 1. Definitions and Clarification of Terms Used in the Specification and Claims

Before addressing details of embodiments described below, some terms are defined or clarified.

The term “acid polymer” refers to a polymer having acidic groups and may also be referred to as a polymeric acid.

The term “acidic group” refers to a group capable of ionizing to donate a hydrogen ion to a Brønsted base.

The term “aqueous” refers to a liquid that has a significant portion of water, and in one embodiment it is at least about 60% by weight water.

The term “carbon nanotube” refers to an allotrope of carbon having a nanostructure where the length-to-diameter ratio exceeds one million.

The term “conductive” or “electrically conductive” as it refers to a material, is intended to mean a material which is inherently or intrinsically capable of electrical conductivity without the addition of carbon black or conductive metal particles.

The term “conductor” and its variants are intended to refer to a layer material, member, or structure having an electrical property such that current flows through such layer material, member, or structure without a substantial drop in potential. The term is intended to include semiconductors. In some embodiments, a conductor will form a layer having a conductivity of at least 10⁻⁷ S/cm.

The term “doped” as it refers to an electrically conductive polymer, is intended to mean that the electrically conductive polymer has a polymeric counterion to balance the charge on the conductive polymer.

The term “doped conductive polymer” is intended to mean the conductive polymer and the polymeric counterion that is associated with it.

The term “electron transport” means when referring to a layer, material, member or structure, such a layer, material, member or structure that promotes or facilitates migration of negative charges through such a layer, material, member or structure into another layer, material, member or structure.

The prefix “fluoro” indicates that one or more available hydrogen atoms have been replaced with a fluorine atom. The terms “fully-fluorinated” and “perfluorinated” are used interchangeably and refer to a compound where all of the available hydrogens bonded to carbon have been replaced by fluorine. The term “highly-fluorinated” refers to a compound in which at least 90% of the available hydrogens bonded to carbon have been replaced by fluorine. The term “non-fluorinated” refers to a compound in which less than 25% of the available hydrogens bonded to carbon have been replaced by fluorine.

The term “fullerene” refers to cage-like, hollow molecules composed of hexagonal and pentagonal groups of carbon atoms. In some embodiments, there are at least 60 carbon atoms present in the molecule.

The term “high-boiling solvent” refers to an organic compound which is a liquid at room temperature and has a boiling point of greater than 120° C.

The term “hole transport” when referring to a layer, material, member, or structure, is intended to mean such layer, material, member, or structure facilitates migration of positive charges through the thickness of such layer, material, member, or structure with relative efficiency and small loss of charge.

The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer.

The term “nanoparticle” refers to a material having a particle size less than 100 nm. In some embodiments, the particle size is less than 10 nm. In some embodiments, the particle size is less than 5 nm.

The term “organic electronic device” is intended to mean a device including one or more semiconductor layers or materials. Organic electronic devices include, but are not limited to: (1) devices that convert electrical energy into radiation (e.g., a light-emitting diode, light emitting diode display, diode laser, or lighting panel), (2) devices that detect signals through electronic processes (e.g., photodetectors photoconductive cells, photoresistors, photoswitches, phototransistors, phototubes, infrared (“IR”) detectors, or biosensors), (3) devices that convert radiation into electrical energy (e.g., a photovoltaic device or solar cell), and (4) devices that include one or more electronic components that include one or more organic semiconductor layers (e.g., a transistor or diode).

The term “polar” refers to a molecule that has a permanent electric dipole.

The term “polymer” is intended to mean a material having at least one repeating monomeric unit. The term includes homopolymers having only one kind, or species, of monomeric unit, and copolymers having two or more different monomeric units, including copolymers formed from monomeric units of different species.

The term “refractive index” with respect to a given material is intended to mean the ratio of the phase velocity of light in a vacuum to the phase velocity of light in the material.

The term “semiconductive” is intended to refer to a material having characteristics of a semiconductor; that is having electrical conductivity greater than insulators but less than good conductors.

The term “work function” is intended to mean the minimum energy needed to remove an electron from a conductive or semiconductive material to a point at infinite distance away from the surface. The work-function is commonly obtained by UPS (Ultraviolet Photoemission Spectroscopy) or Kelvin-probe contact potential differential measurement.

Although light-emitting materials may also have some charge transport properties, the terms “hole transport layer, material, member, or structure” and “electron transport layer, material, member, or structure” are not intended to include a layer, material, member, or structure whose primary function is light emission.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. In the Formulae, the letters Q, R, T, W, X, Y, and Z are used to designate atoms or groups which are defined within. All other letters are used to designate conventional atomic symbols. Group numbers corresponding to columns within the Periodic Table of the elements use the “New Notation” convention as seen in the CRC Handbook of Chemistry and Physics, 81^{st} Edition (2000).

To the extent not described herein, many details regarding specific materials, processing acts, and circuits are conventional and may be found in textbooks and other sources within the organic light-emitting diode display, lighting source, photodetector, photovoltaic, and semiconductive member arts.

### 2. Doped Electrically Conductive Polymers

The doped electrically conductive polymer has a polymeric counterion derived from a polymeric acid to balance the charge on the conductive polymer.

a. Electrically Conductive Polymer

Any electrically conductive polymer can be used in the new composition. In some embodiments, the electrically conductive polymer will form a film which has a conductivity greater than 0.1 S/cm. Thus, the new compositions described herein can be used to form films having a conductivity greater than 100 S/cm.

The conductive polymers suitable for the new composition are made from at least one monomer which, when polymerized alone, forms an electrically conductive homopolymer. Such monomers are referred to herein as “conductive precursor monomers.” Monomers which, when polymerized alone form homopolymers which are not electrically conductive, are referred to as “non-conductive precursor monomers.” The conductive polymer can be a homopolymer or a copolymer. Conductive copolymers suitable for the new composition can be made from two or more conductive precursor monomers or from a combination of one or more conductive precursor monomers and one or more non-conductive precursor monomers.

In some embodiments, the conductive polymer is made from at least one conductive precursor monomer selected from thiophenes, pyrroles, anilines, and polycyclic aromatics. The term “polycyclic aromatic” refers to compounds having more than one aromatic ring. The rings may be joined by one or more bonds, or they may be fused together. The term “aromatic ring” is intended to include heteroaromatic rings. A “polycyclic heteroaromatic” compound has at least one heteroaromatic ring.

In some embodiments, the conductive polymer is made from at least one precursor monomer selected from thiophenes, selenophenes, tellurophenes, pyrroles, anilines, and polycyclic aromatics. The polymers made from these monomers are referred to herein as polythiophenes, poly(selenophenes), poly(tellurophenes), polypyrroles, polyanilines, and polycyclic aromatic polymers, respectively. The term “polycyclic aromatic” refers to compounds having more than one aromatic ring. The rings may be joined by one or more bonds, or they may be fused together. The term “aromatic ring” is intended to include heteroaromatic rings. A “polycyclic heteroaromatic” compound has at least one heteroaromatic ring. In some embodiments, the polycyclic aromatic polymers are poly(thienothiophenes).

In some embodiments, monomers contemplated for use to form the electrically conductive polymer in the new composition comprise Formula I below:

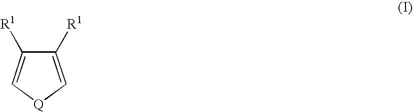

wherein:
Q is selected from the group consisting of S, Se, and Te;
R¹ is independently selected so as to be the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, alcohol, benzyl, carboxylate, ether, ether carboxylate, amidosulfonate, ether sulfonate, ester sulfonate, and urethane; or both R¹ groups together may form an alkylene or alkenylene chain completing a 3, 4, 5, 6, or 7-membered aromatic or alicyclic ring, which ring may optionally include one or more divalent nitrogen, selenium, tellurium, sulfur or oxygen atoms.

As used herein, the term “alkyl” refers to a group derived from an aliphatic hydrocarbon and includes linear, branched and cyclic groups which may be unsubstituted or substituted. The term “heteroalkyl” is intended to mean an alkyl group, wherein one or more of the carbon atoms within the alkyl group has been replaced by another atom, such as nitrogen, oxygen, sulfur, and the like. The term “alkylene” refers to an alkyl group having two points of attachment.

As used herein, the term “alkenyl” refers to a group derived from an aliphatic hydrocarbon having at least one carbon-carbon double bond, and includes linear, branched and cyclic groups which may be unsubstituted or substituted. The term “heteroalkenyl” is intended to mean an alkenyl group, wherein one or more of the carbon atoms within the alkenyl group has been replaced by another atom, such as nitrogen, oxygen, sulfur, and the like. The term “alkenylene” refers to an alkenyl group having two points of attachment.

As used herein, the following terms for substituent groups refer to the formulae given below:

| | |
|---|---|
| “alcohol” | —R³—OH |
| “amido” | —R³—C(O)N(R⁶)R⁶ |
| “amidosulfonate” | —R³—C(O)N(R⁶)R⁴—SO₃Z |
| “benzyl” | —CH₂—C₆H₅ |
| “carboxylate” | —R³—C(O)O—Z or —R³—O—C(O)—Z |
| “ether” | —R³—(O—R⁵)ₚ—O—R⁵ |
| “ether carboxylate” | —R³—O—R⁴—C(O)O—Z or |
| | —R³—O—R⁴—O—C(O)—Z |
| “ether sulfonate” | —R³—O—R⁴—SO₃Z |
| “ester sulfonate” | —R³—O—C(O)—R⁴—SO₃Z |
| “sulfonimide” | —R³—SO₂—NH—SO₂—R⁵ |
| “urethane” | —R³—O—C(O)—N(R⁶)₂ |

where all “R” groups are the same or different at each occurrence and:
   R³ is a single bond or an alkylene group
   R⁴ is an alkylene group
   R⁵ is an alkyl group
   R⁶ is hydrogen or an alkyl group
   p is 0 or an integer from 1 to 20
   Z is H, alkali metal, alkaline earth metal, N(R⁵)₄ or R⁵
      Any of the above groups may further be unsubstituted or substituted, and any group may have F substituted for one or more hydrogens, including perfluorinated groups. In some embodiments, the alkyl and alkylene groups have from 1-20 carbon atoms.

In some embodiments, in the monomer, both R¹ together form—W—(CY¹Y²)ₘ—W—, where m is 2 or 3, W is O, S, Se, PO, NR⁶, Y¹ is the same or different at each occurrence and is hydrogen or fluorine, and Y² is the same or different at each occurrence and is selected from hydrogen, halogen, alkyl, alcohol, amidosulfonate, benzyl, carboxylate, ether, ether carboxylate, ether sulfonate, ester sulfonate, and urethane, where the Y groups may be partially or fully fluorinated. In some embodiments, all Y are hydrogen. In some embodiments, the polymer is poly(3,4-ethylenedioxythiophene). In some embodiments, at least one Y group is not hydrogen. In some embodiments, at least one Y group is a substituent having F substituted for at least one hydrogen. In some embodiments, at least one Y group is perfluorinated.

In some embodiments, the monomer has Formula I(a):

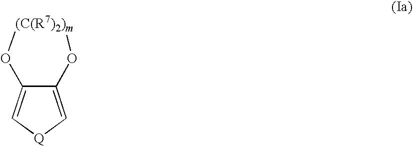

wherein:
Q is selected from the group consisting of S, Se, and Te;
R⁷ is the same or different at each occurrence and is selected from hydrogen, alkyl, heteroalkyl, alkenyl, heteroalkenyl, alcohol, amidosulfonate, benzyl, carboxylate, ether, ether carboxylate, ether sulfonate, ester sulfonate, and urethane, with the proviso that at least one R⁷ is not hydrogen, and
m is 2 or 3.

In some embodiments of Formula I(a), m is two, one R⁷ is an alkyl group of more than 5 carbon atoms, and all other R⁷ are hydrogen. In some embodiments of Formula I(a), at least one R⁷ group is fluorinated. In some embodiments, at least one R⁷ group has at least one fluorine substituent. In some embodiments, the R⁷ group is fully fluorinated.

In some embodiments of Formula I(a), the R⁷ substituents on the fused alicyclic ring on the monomer offer improved solubility of the monomers in water and facilitate polymerization in the presence of the fluorinated acid polymer.

In some embodiments of Formula I(a), m is 2, one R⁷ is sulfonic acid-propylene-ether-methylene and all other R⁷ are hydrogen. In some embodiments, m is 2, one R⁷ is propyl-ether-ethylene and all other R⁷ are hydrogen. In some embodiments, m is 2, one R⁷ is methoxy and all other R⁷ are hydrogen. In some embodiments, one R⁷ is sulfonic acid difluoromethylene ester methylene (—CH₂—O—C(O)—CF₂—SO₃H), and all other R⁷ are hydrogen.

In some embodiments, pyrrole monomers contemplated for use to form the electrically conductive polymer in the new composition comprise Formula II below.

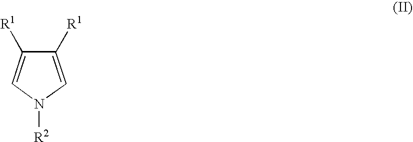

where in Formula II:
R¹ is independently selected so as to be the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, alcohol, benzyl, carboxylate, ether, amidosulfonate, ether carboxylate, ether sulfonate, ester sulfonate, and urethane; or both R¹ groups together may form an alkylene or alkenylene chain completing a 3, 4, 5, 6, or 7-membered aromatic or alicyclic ring, which ring may optionally include one or more divalent nitrogen, sulfur, selenium, tellurium, or oxygen atoms; and
R² is independently selected so as to be the same or different at each occurrence and is selected from hydrogen, alkyl, alkenyl, aryl, alkanoyl, alkylthioalkyl, alkylaryl, arylalkyl, amino, epoxy, silane, siloxane, alcohol, benzyl, carboxylate, ether, ether carboxylate, ether sulfonate, ester sulfonate, and urethane.

In some embodiments, R¹ is the same or different at each occurrence and is independently selected from hydrogen, alkyl, alkenyl, alkoxy, cycloalkyl, cycloalkenyl, alcohol, benzyl, carboxylate, ether, amidosulfonate, ether carboxylate, ether sulfonate, ester sulfonate, urethane, epoxy, silane, siloxane, and alkyl substituted with one or more of sulfonic acid, carboxylic acid, acrylic acid, phosphoric acid, phosphonic acid, halogen, nitro, cyano, hydroxyl, epoxy, silane, or siloxane moieties.

In some embodiments, R² is selected from hydrogen, alkyl, and alkyl substituted with one or more of sulfonic acid, carboxylic acid, acrylic acid, phosphoric acid, phosphonic acid, halogen, cyano, hydroxyl, epoxy, silane, or siloxane moieties.

In some embodiments, the pyrrole monomer is unsubstituted and both R¹ and R² are hydrogen.

In some embodiments, both R¹ together form a 6- or 7-membered alicyclic ring, which is further substituted with a group selected from alkyl, heteroalkyl, alcohol, benzyl, carboxylate, ether, ether carboxylate, ether sulfonate, ester sulfonate, and urethane. These groups can improve the solubility of the monomer and the resulting polymer. In some embodiments, both R¹ together form a 6- or 7-membered alicyclic ring, which is further substituted with an alkyl group. In some embodiments, both R¹ together form a 6- or 7-membered alicyclic ring, which is further substituted with an alkyl group having at least 1 carbon atom. In some embodiments, both R¹ together form —O—(CHY)ₘ—O—, where m is 2 or 3, and Y is the same or different at each occurrence and is selected from hydrogen, alkyl, alcohol, benzyl, carboxylate, amidosulfonate, ether, ether carboxylate, ether sulfonate, ester sulfonate, and urethane. In some embodiments, at least one Y group is not hydrogen. In some embodiments, at least one Y group is a substituent having F substituted for at least one hydrogen. In some embodiments, at least one Y group is perfluorinated.

In some embodiments, aniline monomers contemplated for use to form the electrically conductive polymer in the new composition comprise Formula III below.

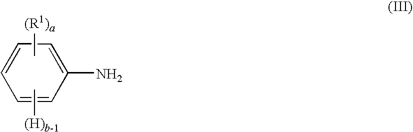

wherein:

a is 0 or an integer from 1 to 4;

b is an integer from 1 to 5, with the proviso that a+b=5; and

R¹ is independently selected so as to be the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, alcohol, benzyl, carboxylate, ether, ether carboxylate, amidosulfonate, ether sulfonate, ester sulfonate, and urethane; or both R¹ groups together may form an alkylene or alkenylene chain completing a 3, 4, 5, 6, or 7-membered aromatic or alicyclic ring, which ring may optionally include one or more divalent nitrogen, sulfur or oxygen atoms.

When polymerized, the aniline monomeric unit can have Formula IV(a) or Formula IV(b) shown below, or a combination of both formulae.

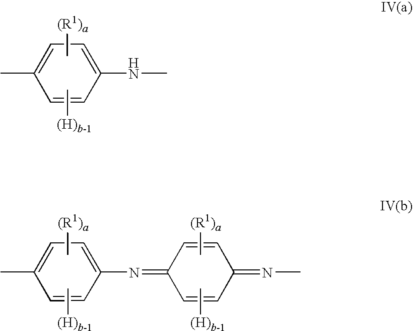

where a, b and R¹ are as defined above.

In some embodiments, the aniline monomer is unsubstituted and a=0.

In some embodiments, a is not 0 and at least one R¹ is fluorinated. In some embodiments, at least one R¹ is perfluorinated.

In some embodiments, fused polycylic heteroaromatic monomers contemplated for use to form the electrically conductive polymer in the new composition have two or more fused aromatic rings, at least one of which is heteroaromatic. In some embodiments, the fused polycyclic heteroaromatic monomer has Formula V:

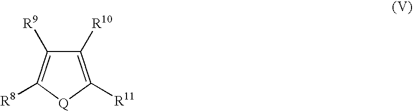

wherein:
Q is S, Se, Te, or NR⁶;
R⁶ is hydrogen or alkyl;
R⁸, R⁹, R¹⁰, and R¹¹ are independently selected so as to be the same or different at each occurrence and are selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, nitrile, cyano, hydroxyl, epoxy, silane, siloxane, alcohol, benzyl, carboxylate, ether, ether carboxylate, amidosulfonate, ether sulfonate, ester sulfonate, and urethane; and
at least one of R⁸ and R⁹, R⁹ and R¹⁰, and R¹⁰ and R¹¹ together form an alkenylene chain completing a 5 or 6-membered aromatic ring, which ring may optionally include one or more divalent nitrogen, sulfur, selenium, tellurium, or oxygen atoms.

In some embodiments, the fused polycyclic heteroaromatic monomer has a formula selected from the group consisting of Formula V(a), V(b), V(c), V(d), V(e), V(f), V(g), V(h), V(i), V(j), and V(k):

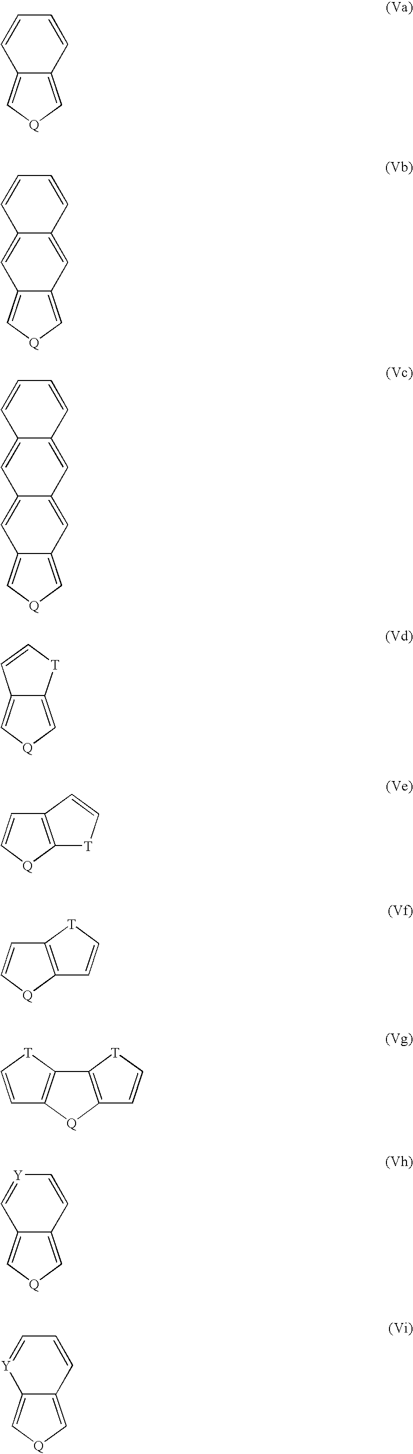

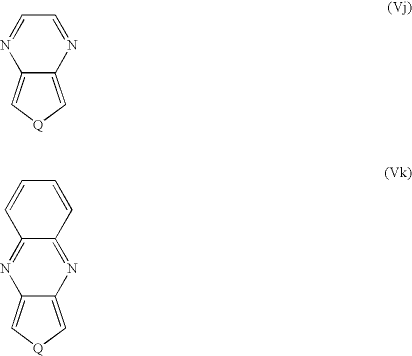

wherein:
Q is S, Se, Te, or NH; and
T is the same or different at each occurrence and is selected from S, NR⁶, O, SiR⁶₂, Se, Te, and PR⁶;
Y is N; and
R⁶ is hydrogen or alkyl.
   The fused polycyclic heteroaromatic monomers may be further substituted with groups selected from alkyl, heteroalkyl, alcohol, benzyl, carboxylate, ether, ether carboxylate, ether sulfonate, ester sulfonate, and urethane. In some embodiments, the substituent groups are fluorinated. In some embodiments, the substituent groups are fully fluorinated.

In some embodiments, the fused polycyclic heteroaromatic monomer is a thieno(thiophene). Such compounds have been discussed in, for example, Macromolecules, 34, 5746-5747 (2001); and Macromolecules, 35, 7281-7286 (2002). In some embodiments, the thieno(thiophene) is selected from thieno(2,3-b)thiophene, thieno(3,2-b)thiophene, and thieno(3,4-b)thiophene. In some embodiments, the thieno(thiophene) monomer is further substituted with at least one group selected from alkyl, heteroalkyl, alcohol, benzyl, carboxylate, ether, ether carboxylate, ether sulfonate, ester sulfonate, and urethane. In some embodiments, the substituent groups are fluorinated. In some embodiments, the substituent groups are fully fluorinated.

In some embodiments, polycyclic heteroaromatic monomers contemplated for use to form the polymer in the new composition comprise Formula VI:

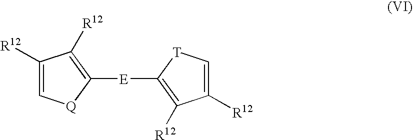

wherein:

Q is S, Se, Te, or NR⁶;

T is selected from S, NR⁶, O, SiR⁶₂, Se, Te, and PR⁶;

E is selected from alkenylene, arylene, and heteroarylene;

R⁶ is hydrogen or alkyl;
R¹² is the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, nitrile, cyano, hydroxyl, epoxy, silane, siloxane, alcohol, benzyl, carboxylate, ether, ether carboxylate, amidosulfonate, ether sulfonate, ester sulfonate, and urethane; or both R¹² groups together may form an alkylene or alkenylene chain completing a 3, 4, 5, 6, or 7-membered aromatic or alicyclic ring, which ring may optionally include one or more divalent nitrogen, sulfur, selenium, tellurium, or oxygen atoms.

In some embodiments, the electrically conductive polymer is a copolymer of a precursor monomer and at least one second monomer. Any type of second monomer can be used, so long as it does not detrimentally affect the desired properties of the copolymer. In some embodiments, the second monomer comprises no more than 50% of the polymer, based on the total number of monomer units. In some embodiments, the second monomer comprises no more than 30%, based on the total number of monomer units. In some embodiments, the second monomer comprises no more than 10%, based on the total number of monomer units.

Exemplary types of second monomers include, but are not limited to, alkenyl, alkynyl, arylene, and heteroarylene. Examples of second monomers include, but are not limited to, fluorene, oxadiazole, thiadiazole, benzothiadiazole, phenylenevinylene, phenyleneethynylene, pyridine, diazines, and triazines, all of which may be further substituted.

In some embodiments, the copolymers are made by first forming an intermediate precursor monomer having the structure A-B-C, where A and C represent precursor monomers, which can be the same or different, and B represents a second monomer. The A-B-C intermediate precursor monomer can be prepared using standard synthetic organic techniques, such as Yamamoto, Stille, Grignard metathesis, Suzuki, and Negishi couplings. The copolymer is then formed by oxidative polymerization of the intermediate precursor monomer alone, or with one or more additional precursor monomers.

In some embodiments, the electrically conductive polymer is selected from the group consisting of a polythiophene, a polypyrrole, a polymeric fused polycyclic heteroaromatic, a copolymer thereof, and combinations thereof.

In some embodiments, the electrically conductive polymer is selected from the group consisting of poly(3,4-ethylenedioxythiophene), unsubstituted polypyrrole, poly(thieno(2,3-b)thiophene), poly(thieno(3,2-b)thiophene), and poly(thieno(3,4-b)thiophene).

b. Non-Fluorinated Polymeric Acid

Any non-fluorinated polymeric acid, which is capable of doping the conductive polymer, can be used to make the new compositions. The use of such acids with conducting polymers such as polythiophenes, polyanilines and polypyrroles is well known in the art. Examples of acidic groups include, but are not limited to, carboxylic acid groups, sulfonic acid groups, sulfonimide groups, phosphoric acid groups, phosphonic acid groups, and combinations thereof. The acidic groups can all be the same, or the polymer may have more than one type of acidic group.

In one embodiment, the acid is a non-fluorinated polymeric sulfonic acid. Some non-limiting examples of the acids are poly(styrenesulfonic acid) (“PSSA”), poly(2-acrylamido-2-methyl-1-propanesulfonic acid) (“PAAMPSA”), and mixtures thereof.

The amount of non-fluorinated polymeric acid present is generally in excess of that required to counterbalance the charge on the conducting polymer. In some embodiments, the ratio of acid equivalents of non-fluorinated polymeric acid to molar equivalents of conducting polymer is in the range of 1-5.

The amount of doped conducting polymer in the composite dispersion is generally at least 0.1 wt. %, based on the total weight of the dispersion. In some embodiments, the wt. % is from 0.2 to 5.

The conductivity of films made from the doped polymer should be at least 0.1 S/cm.

c. Preparation of Doped Electrically Conductive Polymer

The doped electrically conductive polymer is formed by oxidative polymerization of the precursor monomer in the presence of the non-fluorinated polymeric acid in an aqueous medium. Oxidative polymerization of such monomers is well known. Oxidants such as sodium or potassium persulfate may be used. In some cases a catalyst, such as ferric sulfate can also be used. The resulting product is an aqueous dispersion of the doped electrically conductive polymer.

### 3. Highly-Fluorinated Acid Polymer

The highly-fluorinated acid polymer (“HFAP”) is used to enhance the work-function of films made from the new composition. The HFAP can be any polymer which is highly-fluorinated and has acidic groups with acidic protons. The acidic groups supply an ionizable proton. In some embodiments, the acidic proton has a pKa of less than 3. In some embodiments, the acidic proton has a pKa of less than 0. In some embodiments, the acidic proton has a pKa of less than −5. The acidic group can be attached directly to the polymer backbone, or it can be attached to side chains on the polymer backbone. Examples of acidic groups include, but are not limited to, carboxylic acid groups, sulfonic acid groups, sulfonimide groups, phosphoric acid groups, phosphonic acid groups, and combinations thereof. The acidic groups can all be the same, or the polymer may have more than one type of acidic group. In some embodiments, the acidic groups are selected from the group consisting of sulfonic acid groups, sulfonamide groups, and combinations thereof.

In some embodiments, the HFAP is at least 95% fluorinated; in some embodiments, fully-fluorinated.

In some embodiments, the HFAP is water-soluble. In some embodiments, the HFAP is dispersible in water. In some embodiments, the HFAP is organic solvent wettable. The term “organic solvent wettable” refers to a material which, when formed into a film, possesses a contact angle no greater than 60° with organic solvents. In some embodiments, wettable materials form films which are wettable by phenylhexane with a contact angle no greater than 55°. The methods for measuring contact angles are well known. In some embodiments, the wettable material can be made from a polymeric acid that, by itself is non-wettable, but with selective additives it can be made wettable.

Examples of suitable polymeric backbones include, but are not limited to, polyolefins, polyacrylates, polymethacrylates, polyimides, polyamides, polyaramids, polyacrylamides, polystyrenes, and copolymers thereof, all of which are highly-fluorinated; in some embodiments, fully-fluorinated.

In one embodiment, the acidic groups are sulfonic acid groups or sulfonimide groups. A sulfonimide group has the formula:

—SO₂—NH—SO₂—R

where R is an alkyl group.

In one embodiment, the acidic groups are on a fluorinated side chain. In one embodiment, the fluorinated side chains are selected from alkyl groups, alkoxy groups, amido groups, ether groups, and combinations thereof, all of which are fully fluorinated.

In one embodiment, the HFAP has a highly-fluorinated olefin backbone, with pendant highly-fluorinated alkyl sulfonate, highly-fluorinated ether sulfonate, highly-fluorinated ester sulfonate, or highly-fluorinated ether sulfonimide groups. In one embodiment, the HFAP is a perfluoroolefin having perfluoro-ether-sulfonic acid side chains. In one embodiment, the polymer is a copolymer of 1,1-difluoroethylene and 2-(1,1-difluoro-2-(trifluoromethyl)allyloxy)-1,1,2,2-tetrafluoroethanesulfonic acid. In one embodiment, the polymer is a copolymer of ethylene and 2-(2-(1,2,2-trifluorovinyloxy)-1,1,2,3,3,3-hexafluoropropoxy)-1,1,2,2-tetrafluoroethanesulfonic acid. These copolymers can be made as the corresponding sulfonyl fluoride polymer and then can be converted to the sulfonic acid form.

In one embodiment, the HFAP is homopolymer or copolymer of a fluorinated and partially sulfonated poly(arylene ether sulfone). The copolymer can be a block copolymer.

In one embodiment, the HFAP is a sulfonimide polymer having Formula IX:

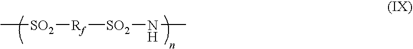

where:
R_{f} is selected from highly-fluorinated alkylene, highly-fluorinated heteroalkylene, highly-fluorinated arylene, and highly-fluorinated heteroarylene, which may be substituted with one or more ether oxygens; and
n is at least 4.
   In one embodiment of Formula IX, R_{f} is a perfluoroalkyl group. In one embodiment, R_{f} is a perfluorobutyl group. In one embodiment, R_{f} contains ether oxygens. In one embodiment n is greater than 10.

In one embodiment, the HFAP comprises a highly-fluorinated polymer backbone and a side chain having Formula X:

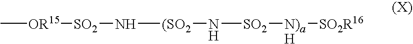

where:
R¹⁵ is a highly-fluorinated alkylene group or a highly-fluorinated heteroalkylene group;
R¹⁶ is a highly-fluorinated alkyl or a highly-fluorinated aryl group; and
a is 0 or an integer from 1 to 4.

In one embodiment, the HFAP has Formula XI:

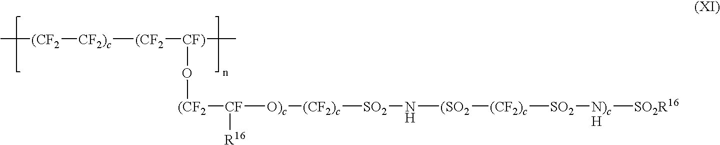

where:

R¹⁶ is a highly-fluorinated alkyl or a highly-fluorinated aryl group;

c is independently 0 or an integer from 1 to 3; and

n is at least 4.

The synthesis of HFAPs has been described in, for example, A. Feiring et al., J. Fluorine Chemistry 2000, 105, 129-135; A. Feiring et al., Macromolecules 2000, 33, 9262-9271; D. D. Desmarteau, J. Fluorine Chem. 1995, 72, 203-208; A. J. Appleby et al., J. Electrochem. Soc. 1993, 140(1), 109-111; and Desmarteau, U.S. Pat. No. 5,463,005.

In one embodiment, the HFAP also comprises a repeat unit derived from at least one highly-fluorinated ethylenically unsaturated compound. The perfluoroolefin comprises 2 to 20 carbon atoms. Representative perfluoroolefins include, but are not limited to, tetrafluoroethylene, hexafluoropropylene, perfluoro-(2,2-dimethyl-1,3-dioxole), perfluoro-(2-methylene-4-methyl-1,3-dioxolane), CF₂═CFO(CF₂)ₜCF═CF₂, where t is 1 or 2, and R_{f}″OCF═CF₂ wherein R_{f}″ is a saturated perfluoroalkyl group of from 1 to about ten carbon atoms. In one embodiment, the comonomer is tetrafluoroethylene.

In one embodiment, the HFAP is a colloid-forming polymeric acid. As used herein, the term “colloid-forming” refers to materials which are insoluble in water, and form colloids when dispersed into an aqueous medium. The colloid-forming polymeric acids typically have a molecular weight in the range of about 10,000 to about 4,000,000. In one embodiment, the polymeric acids have a molecular weight of about 100,000 to about 2,000,000. Colloid particle size typically ranges from 2 nanometers (nm) to about 140 nm. In one embodiment, the colloids have a particle size of 2 nm to about 30 nm. Any highly-fluorinated colloid-forming polymeric material having acidic protons can be used.

Some of the polymers described hereinabove may be formed in non-acid form, e.g., as salts, esters, or sulfonyl fluorides. They will be converted to the acid form for the preparation of conductive compositions, described below.

In some embodiments, HFAP include a highly-fluorinated carbon backbone and side chains represented by the formula

—(O—CF₂CFR_{f}³)ₐ—O—CF₂CFR_{f}⁴SO₃E⁵

wherein R_{f}³ and R_{f}⁴ are independently selected from F, Cl or a highly-fluorinated alkyl group having 1 to 10 carbon atoms, a=0, 1 or 2, and E⁵. In some cases E⁵ can be a cation such as Li, Na, or K, and be converted to the acid form.

In some embodiments, the HFAP can be the polymers disclosed in U.S. Pat. No. 3,282,875 and in U.S. Pat. Nos. 4,358,545 and 4,940,525. In some embodiments, the HFAP comprises a perfluorocarbon backbone and the side chain represented by the formula

—O—CF₂CF(CF₃)—O—CF₂CF₂SO₃E⁵

where E⁵ is as defined above. HFAPs of this type are disclosed in U.S. Pat. No. 3,282,875 and can be made by copolymerization of tetrafluoroethylene (TFE) and the perfluorinated vinyl ether CF₂═CF—O—CF₂CF(CF₃)—O—CF₂CF₂SO₂F, perfluoro(3,6-dioxa-4-methyl-7-octenesulfonyl fluoride) (PDMOF), followed by conversion to sulfonate groups by hydrolysis of the sulfonyl fluoride groups and ion exchanged as necessary to convert them to the desired ionic form. An example of a polymer of the type disclosed in U.S. Pat. Nos. 4,358,545 and 4,940,525 has the side chain —O—CF₂CF₂SO₃E⁵, wherein E⁵ is as defined above. This polymer can be made by copolymerization of tetrafluoroethylene (TFE) and the perfluorinated vinyl ether CF₂═CF—O—CF₂CF₂SO₂F, perfluoro(3-oxa-4-pentenesulfonyl fluoride) (POPF), followed by hydrolysis and further ion exchange as necessary.

One type of HFAP is available commercially as aqueous Nafion® dispersions, from E. I. du Pont de Nemours and Company (Wilmington, Del.).

In the composite dispersion described herein, the ratio of acid equivalent of HFAP to acid equivalent of non-fluorinated doping acid is at least 0.1, and no greater than 2; in some embodiments, no greater than 1.

### 4. Solvent

The solvent is a high-boiling, polar organic liquid. The boiling point of the solvent is at least 100° C. In some embodiments, the boiling point is greater than 120° C.; in some embodiments, greater than 150° C. The solvent is soluble in, miscible with, or dispersible in water. Examples of solvents include, but are not limited to ethylene glycol, dimethlsulfoxide, dimethylacetamide, and N-methylpyrrolidone. Mixtures of solvents may also be used.

The solvent is generally present in the composite dispersion in the amount of from 1 to 15 wt. %, based on the total weight of the dispersion; in some embodiments, from 5 to 10 wt. %.

### 5. Semiconductive Metal Oxide Nanoparticles

The nanoparticles are small particles of mixed oxides which are semiconductive. The phrase “mixed oxide” refers to oxides having two or more different cations. Suitable materials include the mixed oxides of the Group 2 elements, the Group 11 elements, the elements in Groups 4, 5, and 6, the Group 8-10 transition elements, and mixed oxides of Groups 12, 13, 14 and 15 elements. In some embodiments, semiconductive metal oxides can be mixed valence metal oxides or non-stoichiometric metal oxides.

Examples of semiconductive metal oxides include, but are not limited to indium-tin-oxide, doped zinc oxides, gallium-indium-tin oxide, zinc-indium-tin oxides, zinc-doped antimony oxides, zinc antimonates, oxygen deficient molybdenum trioxide, vanadium pentoxide, and the like. In some embodiments, mixtures of metal oxides are used.

In some embodiments, the nano-particles are surface-treated with a coupling agent to be compatible with the aqueous electrically conducting polymers. The class of surface modifiers includes, but not limited to silanes, titanates, zirconates, aluminate and polymeric dispersant. The surface modifiers contain chemical functionality, examples of which include, but are not limited, to nitrile, amino, cyano, alkyl amino, alkyl, aryl, alkenyl, alkoxy, aryloxy, sulfonic acid, acrylic acid, phosphoric acid, and alkali salts of the above acids, acrylate, sulfonates, amidosulfonate, ether, ether sulfonate, estersulfonate, alkylthio, and arylthio. In one embodiment, the chemical functionality may include a croslinker such as expoxy, alkylvinyl and arylvinyl group to react with the conducting polymer in the nano-composite or hole-transporting material on the next upper layer. In one embodiment, the surface modifiers are fluorinated, or pefluorinated, such as tetrafluoro-ethyltrifluoro-vinyl-ether triethoxysilane, perfluorobutane-triethoxysilane, perfluorooctyltriethoxysilane, bis(trifluoropropyl)-tetramethyldisilazane, and bis(3-triethoxysilyl)propyl tetrasulfide.

In some embodiments, the particle size is less than 10 nm. In some embodiments, the particle size is less than 5 nm.

Weight percentage of semiconductive oxide nano-particles in the composite dispersion is in the range of 5-15 wt. %, based on the total weight of the dispersion. The weight ratio of the semiconductive oxide relative to the total of other solids (doped conducting polymer, HFAP, and optional additive) is at least two. The weight ratio of semiconductive oxide nanoparticles to conductive polymer is generally in the range of 5 to 10.

### 6. Other Additives

In some embodiments, an additional additive is present. The optional additive is selected from the group consisting of carbon fullerenes, nanotubes and combinations thereof.

Fullerenes are an allotrope of carbon characterized by a closed-cage structure consisting of an even number of three-coordinate carbon atoms devoid of hydrogen atoms. The fullerenes are well known and have been extensively studied.

Examples of fullerenes include C60, C60-PCMB, and C70, shown below,

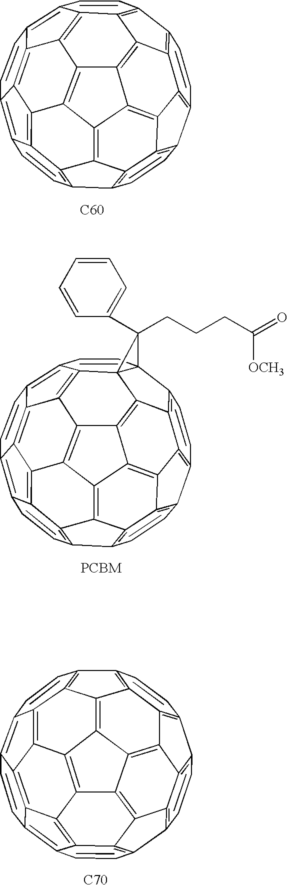

as well as C84 and higher fullerenes. Any of the fullerenes may be derivatized with a (3-methoxycarbonyl)-propyl-1-phenyl group (“PCBM”), such as C70-PCBM, C84-PCBM, and higher analogs. Combinations of fullerenes can be used.

In some embodiments, the fullerene is selected from the group consisting of C60, C60-PCMB, C70, C70-PCMB, and combinations thereof.

Carbon nanotubes have a cylindrical shape. The nanotubes can be single-walled or multi-walled. The materials are made by methods including arc discharge, laser ablation, high pressure carbon monoxide, and chemical vapor deposition. The materials are well known and commercially available. In some embodiments, single-walled nanotubes are used.

The amount of additive, when present, is generally at least 0.2 wt. %, based on the total weight of the dispersion.

### 7. Preparation of the Composite Dispersion and Films

In the following discussion, the doped conductive polymer, HFAP, solvent, metal oxide nanoparticles, and optional additives will be referred to in the singular. However, it is understood that more than one of any or all of these may be used.

The new electrically conductive polymer composition is prepared by first forming the doped conductive polymer and then adding the HFAP, the solvent, the semiconductive metal oxide nanoparticles, and optional additives in any order.

The doped electrically conductive polymer is generally formed by oxidative polymerization of the precursor monomer in the presence of the non-fluorinated polymeric acid in an aqueous medium. Many of these materials are commercially available. The HFAP can be first dissolved or dispersed in the solvent or a solvent/water mixture. The metal oxide nanoparticles can similarly be dispersed in water or a solvent/water mixture. These mixtures can then be added to an aqueous dispersion of the doped conductive polymer. The metal oxide nanoparticles can also be dispersed with the HFAP or with the doped conductive polymer.

Alternatively, the metal oxide nanoparticles can be added to the doped conductive polymer dispersion directly as a solid. The solvent and HFAP can be added to this mixture.

The optional additive, when present, can be added at any point. The additive can be added as a dispersion in water or a solvent/water mixture, or it can be added directly as a solid.

In some embodiments, the pH is increased either prior to or after the addition of the metal oxide nanoparticles and, optionally, the additive. The pH can be adjusted by treatment with cation exchange resins and/or base resins prior to the addition of the metal oxide nanoparticles and, optionally, the additive. In some embodiments, the pH is adjusted by the addition of aqueous base solution. Cations for the base can be, but are not limited to, alkali metal, alkaline earth metal, ammonium, and alkylammonium. In some embodiments, alkali metal is preferred over alkaline earth metal cations.

Films made from the composite aqueous dispersions described herein, are hereinafter referred to as “the new films described herein”. The films can be made using any liquid deposition technique, including continuous and discontinuous techniques. Continuous deposition techniques, include but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing.

The films thus formed are smooth, relatively transparent, and can have a conductivity greater than 100 S/cm.

The films have a refractive index that is generally greater than 1.7. A high refractive index is desired in order to more closely match adjacent layers in devices, which typically have a high refractive index. A large difference in refractive index between adjacent layers can lead to cavity effects. The difference in refractive index will lead to a variation in OLED device performance with layer thickness.

### 8. Buffer Layers

Organic light-emitting diodes (OLEDs) are an organic electronic device comprising an organic layer capable of electroluminescence. OLEDs can have the following configuration:
anode/buffer layer/EL material/cathode
   with additional layers between the electrodes. Electrically conducting polymers having low conductivity in the range of 10⁻³ to 10⁻⁷ S/cm are commonly used as the buffer layer in direct contact with an electrically conductive, inorganic oxide anode such as ITO. However, films of the new compositions having conductivity greater than 100 S/cm can serve both anode and buffer layer functions.

In another embodiment of the invention, there are provided buffer layers deposited from composite aqueous dispersions. The term “buffer layer” or “buffer material” is intended to mean electrically conductive or semiconductive materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer. Continuous deposition techniques, inlcude but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing.

### 9. Electronic Devices

The new films described herein can be used in electronic devices where the high conductivity and high work-function is desired in combination with transparency. In some embodiments, the films are used as electrodes. In some embodiments, the films are used as transparent conductive coatings.

Examples of electronic devices include, but are not limited to: (1) a device that converts electrical energy into radiation (e.g., a light-emitting diode, light emitting diode display, diode laser, or lighting panel), (2) a device that detects a signal using an electronic process (e.g., a photodetector, a photoconductive cell, a photoresistor, a photoswitch, a phototransistor, a phototube, an infrared (“IR”) detector, or a biosensors), (3) a device that converts radiation into electrical energy (e.g., a photovoltaic device or solar cell), (4) a device that includes one or more electronic components that include one or more organic semiconductor layers (e.g., a transistor or diode), (5) an electrolytic capacitor, or any combination of devices in items (1) through (5).

In some embodiments, the new films described herein are useful as an electrically conductive polymer cathode, for example, in Tantalum/Ta2O5 or Aluminum/Al2O3 capacitors.

In another embodiment of the invention, there are provided electronic devices comprising at least one electroactive layer positioned between two electrical contact layers, wherein the device further includes the new buffer layer. The term “electroactive” when referring to a layer or material is intended to mean a layer or material that exhibits electronic or electro-radiative properties. An electroactive layer material may emit radiation or exhibit a change in concentration of electron-hole pairs when receiving radiation.

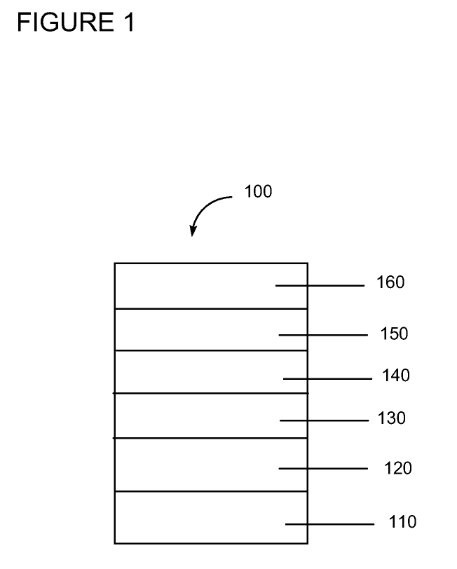

As shown in FIG. 1, one embodiment of a device, 100, has an anode layer 110, an electroactive layer 140, and a cathode layer 160. Also shown are three optional layers: buffer layer 120; hole transport layer 130; and electron injection/transport layer 150.

The device may include a support or substrate (not shown) that can be adjacent to the anode layer 110 or the cathode layer 160. Most frequently, the support is adjacent the anode layer 110. The support can be flexible or rigid, organic or inorganic. Examples of support materials include, but are not limited to, glass, ceramic, metal, and plastic films.

The anode layer 110 is an electrode that is more efficient for injecting holes compared to the cathode layer 160. Thus, the anode has a higher work-function than the cathode. The new films of this invention described herein are particularly suitable as the anode layer because of their high conductivity and high work-function. In some embodiments, the new films have a conductivity of 100 S/cm or greater. In some embodiments, they have a conductivity of 200 S/cm or greater. The films are deposited onto substrates using a variety of techniques well-known to those skilled in the art. Typical deposition techniques include liquid deposition (continuous and discontinuous techniques), and thermal transfer.

In some embodiments, the new films described herein are used alone as an anode without optional buffer layer 120. In this embodiment, the new films of this invention serve the functions of both the anode layer and the buffer layer.

In some embodiments, the new films described herein are used as the top layer in a bilayer or multilayer anode. The other anode layers can include materials containing a metal, mixed metal, alloy, metal oxide or mixed oxide. Suitable materials include the mixed oxides of the Group 2 elements (i.e., Be, Mg, Ca, Sr, Ba, Ra), the Group 11 elements, the elements in Groups 4, 5, and 6, and the Group 8-10 transition elements. If the anode layer 110 is to be light transmitting, mixed oxides of Groups 12, 13 and 14 elements may be used. As used herein, the phrase “mixed oxide” refers to oxides having two or more different cations selected from the Group 2 elements or the Groups 12, 13, or 14 elements. Examples of suitable materials include, but are not limited to, indium-tin-oxide (“ITO”). indium-zinc-oxide (“IZO”), aluminum-tin-oxide (“ATO”), aluminum-zinc-oxide (“AZO”), zirconium-tin-oxide (“ZTO”), gold, silver, copper, and nickel.

In some embodiments, the mixed oxide layer is patterned. The pattern may vary as desired. The layer can be formed in a pattern by, for example, using a discontinuous deposition technique. Alternatively, the layer can be applied as an overall layer (also called blanket deposit) and subsequently patterned using, for example, a patterned resist layer and wet chemical or dry etching techniques. Other processes for patterning that are well known in the art can also be used.

Optional buffer layer 120 may be present adjacent to the anode layer 110. The term “buffer layer” or “buffer material” is intended to mean electrically conductive or semiconductive materials having conductivity usually in the range between 10⁻³ to 10⁻⁷ S/cm, but higher conductivity can be used for some device geometries. The buffer layer may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device.

In some embodiments, the buffer layer 120 comprises the new film described herein, where the conductivity is 100 S/cm or less.

In some embodiments, optional hole transport layer 130 is present. between anode layer 110 and electroactive layer 140. In some embodiments, optional hole transport layer is present between a buffer layer 120 and electroactive layer 140. Examples of hole transport materials have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 1,1-bis[(di-4-tolylamino)phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate.

Depending upon the application of the device, the electroactive layer 140 can be a light-emitting layer that is activated by an applied voltage (such as in a light-emitting diode or light-emitting electrochemical cell), a layer of material that responds to radiant energy and generates a signal with or without an applied bias voltage (such as in a photodetector). In one embodiment, the electroactive material is an organic electroluminescent (“EL”) material, Any EL material can be used in the devices, including, but not limited to, small molecule organic fluorescent compounds, fluorescent and phosphorescent metal complexes, conjugated polymers, and mixtures thereof. Examples of fluorescent compounds include, but are not limited to, pyrene, perylene, rubrene, coumarin, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Electroluminescent emissive layers comprising a charge carrying host material and a metal complex have been described by Thompson et al., in U.S. Pat. No. 6,303,238, and by Burrows and Thompson in published PCT applications WO 00/70655 and WO 01/41512. Examples of conjugated polymers include, but are not limited to poly(phenylenevinylenes), polyfluorenes, poly(spirobifluorenes), polythiophenes, poly(p-phenylenes), copolymers thereof, and mixtures thereof.

Optional layer 150 can function both to facilitate electron injection/transport, and can also serve as a confinement layer to prevent quenching reactions at layer interfaces. More specifically, layer 150 may promote electron mobility and reduce the likelihood of a quenching reaction if layers 140 and 160 would otherwise be in direct contact. Examples of materials for optional layer 150 include, but are not limited to, metal chelated oxinoid compounds, such as bis(2-methyl-8-quinolinolato)(para-phenyl-phenolato)aluminum(III) (BAIQ) and tris(8-hydroxyquinolato)aluminum (Alq₃); tetrakis(8-hydroxyquinolinato)zirconium; azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthroline derivatives such as 9,10-diphenylphenanthroline (DPA) and 2,9-dimethyl-4,7-diphenyl-1,10-phenanthroline (DDPA); and any one or more combinations thereof. Alternatively, optional layer 150 may be inorganic and comprise BaO, LiF, Li₂O, or the like.

The cathode layer 160 is an electrode that is particularly efficient for injecting electrons or negative charge carriers. The cathode layer 160 can be any metal or nonmetal having a lower work function than the first electrical contact layer (in this case, the anode layer 110). As used herein, the term “lower work function” is intended to mean a material having a work function no greater than about 4.4 eV. As used herein, “higher work function” is intended to mean a material having a work function of at least approximately 4.4 eV.

Materials for the cathode layer can be selected from alkali metals of Group 1 (e.g., Li, Na, K, Rb, Cs,), the Group 2 metals (e.g., Mg, Ca, Ba, or the like), the Group 12 metals, the lanthanides (e.g., Ce, Sm, Eu, or the like), and the actinides (e.g., Th, U, or the like). Materials such as aluminum, indium, yttrium, and combinations thereof, may also be used. Specific non-limiting examples of materials for the cathode layer 160 include, but are not limited to, barium, lithium, cerium, cesium, europium, rubidium, yttrium, magnesium, samarium, and alloys and combinations thereof.

The cathode layer 160 is usually formed by a chemical or physical vapor deposition process. In some embodiments, the cathode layer will be patterned, as discussed above in reference to the anode layer 110.

Other layers in the device can be made of any materials which are known to be useful in such layers upon consideration of the function to be served by such layers.

In some embodiments, an encapsulation layer (not shown) is deposited over the contact layer 160 to prevent entry of undesirable components, such as water and oxygen, into the device 100. Such components can have a deleterious effect on the organic layer 140. In one embodiment, the encapsulation layer is a barrier layer or film. In one embodiment, the encapsulation layer is a glass lid.

Though not depicted, it is understood that the device 100 may comprise additional layers. Other layers that are known in the art or otherwise may be used. In addition, any of the above-described layers may comprise two or more sub-layers or may form a laminar structure. Alternatively, some or all of anode layer 110, the buffer layer 120, the hole transport layer 130, the electron transport layer 150, cathode layer 160, and other layers may be treated, especially surface treated, to increase charge carrier transport efficiency or other physical properties of the devices. The choice of materials for each of the component layers is preferably determined by balancing the goals of providing a device with high device efficiency with device operational lifetime considerations, fabrication time and complexity factors and other considerations appreciated by persons skilled in the art. It will be appreciated that determining optimal components, component configurations, and compositional identities would be routine to those of ordinary skill of in the art.

In one embodiment, the different layers have the following range of thicknesses: anode 110, 500-5000 Å, in one embodiment 1000-2000 Å; optional buffer layer 120, 50-2000 Å, in one embodiment 200-1000 Å; optional hole transport layer 130, 50-2000 Å, in one embodiment 100-1000 Å; electroactive layer 140, 10-2000 Å, in one embodiment 100-1000 Å; optional electron transport layer 150, 50-2000 Å, in one embodiment 100-1000 Å; cathode 160, 200-10000 Å, in one embodiment 300-5000 Å. The location of the electron-hole recombination zone in the device, and thus the emission spectrum of the device, can be affected by the relative thickness of each layer. Thus the thickness of the electron-transport layer should be chosen so that the electron-hole recombination zone is in the light-emitting layer. The desired ratio of layer thicknesses will depend on the exact nature of the materials used.

In operation, a voltage from an appropriate power supply (not depicted) is applied to the device 100. Current therefore passes across the layers of the device 100. Electrons enter the organic polymer layer, releasing photons. In some OLEDs, called active matrix OLED displays, individual deposits of photoactive organic films may be independently excited by the passage of current, leading to individual pixels of light emission. In some OLEDs, called passive matrix OLED displays, deposits of photoactive organic films may be excited by rows and columns of electrical contact layers.

Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

It is to be appreciated that certain features of the invention which are, for clarity, described above and below in the context of separate embodiments, may also be provided in combination in a single embodiment. Conversely, various features of the invention that are, for brevity, described in the context of a single embodiment, may also be provided separately or in any subcombination. Further, reference to values stated in ranges include each and every value within that range.

### EXAMPLES

### A) General Procedure of Four-Probe Electrical Resistance Measurement and Calculation of Electrical Conductivity

Film sample preparation for electrical resistance measurement is described in each Example where film-baking conditions are specified. Silver paste was then painted perpendicular to the length of a thin strip of film sample to form four electrodes. The two inner parallel electrodes were about 0.3 cm to 0.5 cm apart and were connected to a Keithley model 616 electrometer for measurement of voltage. The two outside parallel electrodes were connected to a Keithley model 225 Current Supplier. A series of corresponding current/voltage data obtained at room temperature was recorded to see whether Ohm's law was followed. All the samples in the Examples followed Ohm's law, which provided a more or less identical resistance of the corresponding current/voltage data. Once resistance measurement was done, the area in the two inner electrodes was measured for thickness with a profilometer. Thickness of the tested films is typically in the range of 1 micrometer (um). Since resistance, thickness, separation length of the two inner electrodes and the width of the filmstrip are known, electrical conductivity is then calculated. The conductivity unit is expressed as S (Siemens)/cm.

### B) General Procedure of Sample Preparation and Work Function Measurement

Film sample was prepared by coating a dispersion on the center of a 30 mm×30 mm glass/indium/tin semiconductive oxide (ITO) substrate. Details of the film coating are given in each Example. The ITO/glass substrates consisted of 15 mm×20 mm ITO area at the center having ITO thickness of 100 to 150 nm. At one corner of 15 mm×20 mm ITO area, ITO film surface extended to the edge of the glass/ITO serves as electrical contact with one of two Kelvin probe electrodes. Prior to spin coating, ITO/glass substrates were cleaned and the ITO side was subsequently treated with oxygen plasma for 15 minutes. Once spin-coated with an aqueous sample dispersion, the deposited layer on the corner of the extended ITO film was removed with a water-wetted cotton-swath tip. The exposed ITO pad was used to make contact with the one of two electrodes of a Kelvin probe. For energy potential measurement, ambient-aged gold film was measured first as a reference prior to measurement of samples. The gold film on a same size of glass was placed in a cavity cut out at the bottom of a square steel container. On the side of the cavity, there are four retention clips to keep sample piece firmly in place. One of the retention clips is attached with electrical wire. The retention clip attached with the electrical wire was clipped on the ITO at the corner for making contact with the one of two electrodes of the Kelvin probe. The gold film was facing up a Kelvin probe tip protruded from the center of a steel lid, which was lowered to slightly above the center of the gold film surface. The lid was then screwed tightly onto the square steel container at four corners. A side port on the square steel container was connected with a tubing to allow nitrogen to sweep the Kelvin probe cell while a nitrogen exit port was capped with a septum in which a steel needle was inserted to maintain ambient pressure. The probe settings were then optimized for the probe and only height of the tip was adjusted during the measurement. The Kelvin probe tip was part of the second electrode which was also connected to a McAllister KP6500* Kelvin Probe meter having the following parameters: 1) frequency (Hz): 230; 2) amplitude (arbitrary): 20; 3) DC offset (volt): varied from sample to sample; 4) upper backing potential (volt): 2; 5) lower backing potential (volt): −2; 6) scan step: 1; 7) trigger delay (degree per full cycle): 0; 8) acquisition(A)/data(D) points: 1024; 9) A/D rate (Hz): 12405@19.0 cycles; 10) D/A delay (milliseconds): 200; 11) set point gradient (unitless): 0.2; 12) step size (volt): 0.001; 13) maximum gradient deviation (volt): 0.001. As soon as the tracking gradient stabilized, the contact potential differential or CPD (expressed in volts) between gold film and probe tip was recorded. The CPD of gold and the probe tip was checked periodically to ensure reliable reference for calculation of energy potential of samples. For CPD measurement of samples with the probe tip, each sample was loaded into the cavity in the same manner as gold film sample. On the retention clip that makes electrical contact with the sample, extra care was taken to ensure that good electrical contact was made with the exposed ITO pad. During the CPD measurement a small stream of nitrogen was flown through the cell without disturbing the probe tip. Once CPD of a sample was recorded, work function of the sample was calculated by adding CPD of the sample to the difference of 4.7 eV and CPD of gold. 4.7 eV is the work function of an ambient-aged gold film [Surface Science, 316, (1994), P380]. The measured work function of a material is thus determined as required energy for removing electron from the surface of the material.

### Example 1

This example illustrates the preparation of an aqueous dispersion of Nafion®/PEDOT-PSSA for incorporation of a semiconductive oxide to produce films having high conductivity, work-function, and refractive index.

A stable aqueous composite dispersion containing PEDOT-PSSA (a conducting polymer), Nafion® (a colloid forming perfluororinated polymeric acid), and a high boiling polar solvent was first prepared for incorporation of a semiconductive oxide. The composite dispersion will be shown to produce films having high conductivity and work-function. Nafion® polymer is a trade name for the copolymer of TFE (tetrafluoroethylene) and PSEPVE (3,6-dioxa-4-methyl-7-octenesulfonic acid), made by E. I. du Pont de Nemours and Company (Wilmington, Del.). Nafion® polymer, (“P-(TFE-PSEPVE)”), used in this example was obtained by the slow removal of water from an aqueous dispersion of Nafion® in vacuum at a temperature below 10° C. The aqueous dispersion of Nafion® was prepared by heating P-(TFE/PSEPVE) having EW (equivalent weight: weight of the polymer per one sulfonic acid group) of 1050 in water only to ˜270° C. The aqueous Nafion® dispersion had 25% (w/w) P-(TFE/PSEPVE) in water and was diluted to ˜12% with deionized water prior to removing water for collecting P-(TFE-PSEPVE). The collected P-(TFE-PSEPVE) solids were soluble or dispersible in many highly polar solvents or mixture of the solvents with water. It should be pointed out that any perfluoropolymeric acids (PFA) could be obtained by removing liquid medium from aqueous or non-aqueous dispersion or solution at a temperature less than the “coalescence temperature” of the PFA. By “coalescence temperature” is meant the temperature at which a dried solid of the PFA is cured to a stable solid which is not re-dispersible in water, other polar solvent or mixtures thereof.

Electrically conducting polymer used in this example is poly(3,4-ethylenedioxythiophene) doped with non-fluorinated poly(styrenesulfonic acid), abbreviated as “PEDOT/PSSA”. PEDOT/PSSA is a well-known electrically conductive polymer. The polymer dispersed in water is commercially available from H. C. Starck GmbH (Leverkuson, Germany) in several grades under a trade name of Baytron-P®. Baytron-P® HCV4, one of the commercial aqueous dispersion products, purchased from Starck was used. The Baytron-P® HCV4 sample was determined gravimetrically to have 1.10% (w/w) solid, which should be PEDOT/PSSA in water. According to the product brochure, the weight ratio of PEDOT:PSSA is 1:2.5.

Before mixing with Baytron-P® HCV4, a Nafion® polymer/ethylene glycol solution and a DMSO (dimethyl sulfoxide)/water solution were prepared first. The latter solution was for reducing PEDOT-PSSA solid % of HCV4, therefore lowering its viscosity. 0.7541 g P-(TFE-PSEPVE) having EW of 1050 was added to 9.2534 g ethylene glycol in a glass vial. The mixture was heated to ˜120° C. until P-(TFE-PSEPVE) solids were all dissolved. Weight % (w/w) of P-(TFE-PSEPVE) in the ethylene glycol solution is 7.51%. A ˜10% (w/w) DMSO in water was made by adding 1.0034 g DMSO to 9.0035 g water. To 2.5066 g Baytron-P® HCV4 was first added slowly with 3.0132 g DMSO/water solution to reduce PEDOT-PSSA solid %, which became 0.48%. To the mixture, 0.5666 g P-(TFE-PSEPVE)/ethylene glycol solution was added. The combined amount of water/DMSO solution and P-(TFE-PSEPVE)/ethylene glycol represents 14.2% (w/w) of combined DMSO and ethylene glycol in the final formulation of HCV4. Based on the amount of PEDOT-PSSA and P-(TFE-PSEPVE), acid equivalent ratio of P-(TFE-PSEPVE) to PSSA is 0.41. This ratio is used for specifying optimal concentration of P-(TFE-PSEPVE) with respect to PSSA for overall consideration of desired electrical conductivity and work function.

Films from the dispersion for electrical resistance measurement were prepared by having a small drop of each dispersion on a 3″×1″ microscope slide. The liquid was spread to cover ⅔ area of the slide before placing on a hot plate set at ˜110° C. in air for drying first. The hot plate was increased to 200° C. for baking in air for 5 minutes. The slide containing a dry film was removed from the hot plate and the film was trimmed to a long strip with a razor blade. Width of the strip ranged from 0.2 cm to 0.7 cm and the length was about 3 cm. Detail of electrical resistance measurement was described in the general procedure. Conductivity of two film samples was measured to be 153.9 S/cm, and 191.7 S/cm.

Films from the dispersion for work-function measurement were prepared by spin-coating at 2,000 rpm on a 30 mm×30 mm glass/indium/tin semiconductive oxide (ITO) substrate. The film was baked in air at 200° C. for 5 minutes. Detail of the measurement was described in the general procedure. Work function was determined to be 5.64 eV. The work function is much higher than the work-function of Baytron-P® HCV4, which is smaller than 5.0 eV.

The aqueous dispersion of PEDOT-PSSA/Nafion® prepared above one year ago, which provides films having high conductivity and high work-function, was used for incorporation of a semiconductive oxide. The semiconductive oxide is zinc antimonite, which has conductivity of about 3×10⁻⁴ S/cm in powder form according to the product brochure from Nissan Chemical Company. It has high refractive index, greater than 1.8 [Journal of Physics and Chemistry of Solids, Vol 65, p 901-906 (2004)]. It should enhance refractive index of PEDOT-PSSA that is usually in the range of 1.5 at 460 nm wavelength. Celnax® CX-Z300H F2, which is an aqueous sol of zinc antimonate, purchased from Nissan Chemical America Corporation in Houston, Tex., was used for addition to the aqueous PEDOT-PSSA/Nafion® dispersion prepared above. 1.7259 g PEDOT-PSSA/Nafion® dispersion was added with 0.1701 g Celnax CX-Z300H F2, which contains 31.1% (w/w) zinc antimonate in water. The mixture formed a smooth, stable dispersion in light of the presence of Nafion®, dimethyl sulfoxide and ethylene glycol. The final composite dispersion contains 12.9 w % DMSO and EG, 2.79 w % zinc antimonate and 1.0 w % PEDOT-PSSA/Nafion®. The acid equivalent ratio of Nafion® polymer to PSSA remains at 0.41, which keeps the work function unchanged. Films from the composite dispersion for electrical resistance measurement were prepared in the manner as above. They were baked at 160° C. for 30 minutes in air. Conductivity of two film samples was measured to be 102.2 S/cm, and 101.0 S/cm. The conductivity is very similar to those without the zinc antimonite. However, having the high weight ratio of zinc antimonate relative to PEDOT-Nafion® provides high refractive index of resulting solid films.

### Example 2

This example illustrates preparation of an aqueous composite dispersion of Nafion®/PEDOT-PSSA/Carbon-nanotube (CNT) for incorporation of a semiconductive oxide to produce films having high conductivity, work-function, and refractive index.

A stable aqueous composite dispersion containing PEDOT-PSSA (a conducting polymer), Nafion® (a colloid forming perfluororinated polymeric acid), carbon nanotubes, and a high boiling polar solvent was first prepared for incorporation of a semiconductive oxide. The composite dispersion without a semiconductive oxide will be shown to produce films having high conductivity and work-function.

CNT used in this example were HIPco* P0244, purchased from CNI (Carbon Nanotechnologies, Inc.) at Houston, Tex., USA. HIPco* P0244 CNT is single-walled nanotubes, which contain about 10% (w/w) residual catalyst. It is made by a process using high-pressure carbon monoxide and then purified by the Company. Nafion® polymer used in this example was described in Example 1. Electrically conducting polymer of PEDOT-PSSA, Baytron-P® HCV4, used in this example was also described in Example 1.

Prior to preparation of a CNT composite dispersion, a Nafion® polymer/ethylene glycol solution and an ethylene glycol/water solution were prepared. The latter solution was for reducing PEDOT-PSSA solid % of HCV4, therefore lowering its viscosity. 0.7538 g P-(TFE-PSEPVE) having EW of 1050 was added to 9.2531 g ethylene glycol in a glass vial. The mixture was heated to ˜120° C. until P-(TFE-PSEPVE) solids were all dissolved. Weight % (w/w) of P-(TFE-PSEPVE) in the ethylene glycol solution is 7.53%. A 10.01% (w/w) ethylene glycol/water solution was made by adding 4.0014 g ethylene glycol to 36.0128 g deionized water.

0.0973 g CNT were first placed in a glass jug. To the CNT solids, 15.5814 g ethylene glycol (10.01%, w/w)/water solution were added, followed with 1.6771 g P-(TFE-PSEPVE), (7.5333% w/w)/ethylene glycol solution and 15.5825 g Baytron-P® HCV4. Based on the quantity of each component, the mixture contains 0.52% (w/w) PEDOT-PSSA, 9.44% (w/w) ethylene glycol, 0.295% (w/w) CNT, 0.384% (w/w) P-(TFE-PSEPVE) polymer and the remaining is water. Based on the amount of PEDOT-PSSA and P-(TFE-PSEPVE), acid equivalent ratio of P-(TFE-PSEPVE) to PSSA is 0.18. The mixture was subjected to sonication for 28 minutes continuously using a Branson Model 450 Sonifier* having power set at #4. The glass jug was immersed in ice water contained in a tray to remove heat produced from intense cavitation during the entire time of sonication. The mixture formed a smooth, stable dispersion without any sign of sedimentation. The pH of the dispersion was measured to be 2.0 using a pH meter (model 63) from Jenco Electronics, Ltd (San Diego, Calif.).

Films from the dispersion for electrical resistance measurement were prepared by having a small drop of each dispersion on a 3″×1″ microscope slide. The liquid was spread to cover ⅔ area of the slide placed on a hot plate set at ˜180° C. in air for drying first. The hot plate was increased to 200° C. for baking in air for 5 minutes. The slide containing a dry film was removed from the hot plate and the film was trimmed to a long strip with a razor blade. Width of the strip ranged from 0.2 cm to 0.7 cm and the length was about 3 cm. The thin strip of film was further baked at 210° C. for 10 minutes. Detail of electrical resistance measurement was described in the general procedure. The baked films were tested for electrical resistance as described in the general procedure. Conductivity of six film samples at room temperature was measured to be 434.2 S/cm, 323.9 S/cm, 420.1 S/cm, 434.6 S/cm, 445.6 S/cm, and 373.3 S/cm.

Films from the dispersion for work-function measurement were prepared by placing one drop of the dispersion on the center of a 30 mm×30 mm glass/indium/tin semiconductive oxide (ITO) substrate. The film was baked in air 150° C. for 5 minutes. Detail of the measurement was described in the general procedure. Work-function was determined to be 5.45 eV. The work-function is much higher than that of Baytron-P® HCV4, which is smaller than 5.0 eV.

The aqueous dispersion of PEDOT-PSSA/Nafion®/CNT dispersion prepared above one year ago, which provides films having high conductivity and high work-function, was used for incorporation of a semiconductive oxide. The semiconductive oxide is zinc antimonate. It has high refractive index and should enhance refractive index of PEDOT-PSSA that is usually in the range of 1.5 at 460 nm wavelength. Celnax* CX-Z300H F2, which is an aqueous sol of zinc antimonate, purchased from Nissan Chemical America Corporation in Houston, Tex., was used for addition to the aqueous PEDOT-PSSA/Nafion®/CNT dispersion prepared above. 2.1069 g PEDOT-PSSA/Nafion®/CNT dispersion was added with 0.2835 g Celnax* CX-Z300H F2, which contains 31.1% (w/w) zinc antimonate in water. The mixture formed a smooth, stable dispersion in light of the presence of Nafion®, CNT, and ethylene glycol. The final composite dispersion contains 3.7 w. % zinc antimonate, 8.32 w % EG, and 1.1 w % PEDOT-PSSA/Nafion®/CNT. The acid equivalent ratio of Nafion® polymer to PSSA remains at 0.18, which keeps the work function unchanged. Films from the composite dispersion for electrical resistance measurement were prepared in the manner as above. They were baked at 160° C. for 30 nmiutes in air. Conductivity of two film samples was measured to be 217.8 S/cm, and 103.9 S/cm. The conductivity is similar to those without the zinc antimonite. However, having the high weight ratio of zinc antimonate relative to PEDOT-Nafion®/CNT provides high refractive index of resulting solid films.

### Example 3

This example also illustrates preparation of an aqueous composite dispersion of Nafion®/PEDOT-PSSA/Carbon-nanotube (CNT) for incorporation of a semiconductive oxide to produce films having high conductivity, work function, and refractive index. CNT used in this example is a different grade.

A stable aqueous composite dispersion containing PEDOT-PSSA (a conducting polymer), Nafion® (a colloid forming perfluororinated polymeric acid), carbon nanotubes, and a high boiling polar solvent was first prepared for incorporation of a semiconductive oxide. The composite dispersion without a semiconductive oxide will be shown to produce films having high conductivity and work-function.

CNT used in this example was E601J, also purchased from CNI (Carbon Nanotechnologies, Inc.) at Houston, Tex., USA. It was made by a chemical vapor deposition process. Nafion® polymer, (“P-(TFE-PSEPVE)”) and PEDOT-PSSA used in Example 1 was also used here.

Prior to preparation of a CNT composite dispersion, a Nafion® polymer/ethylene glycol solution and an ethylene glycol/water solution were prepared. The solution was for reducing PEDOT-PSSA solid % of HCV4, therefore reducing its viscosity. 0.7538 g P-(TFE-PSEPVE) having EW of 1050 was added to 9.2531 g ethylene glycol in a glass vial. The mixture was heated to ˜120° C. until P-(TFE-PSEPVE) solids were all dissolved. Weight % (w/w) of P-(TFE-PSEPVE) in the ethylene glycol solution is 7.533%. A 10.0% (w/w) ethylene glycol/water solution was made by adding 2.0017 g ethylene glycol to 18.007 g deionized water.

0.0972 g CNT were first placed in a glass jug. To the CNT solids, 15.5794 g ethylene glycol (10.0%, w/w)/water solution were added, followed with 1.6974 g P-(TFE-PSEPVE), (7.5333% w/w) ethylene glycol solution and 15.5800 g Baytron-P® HCV4. Based on the quantity of each component, the mixture contains 0.52% (w/w) PEDOT-PSSA, 9.49% (w/w) ethylene glycol, 0.295% (w/w) CNT, 0.39% (w/w) P-(TFE-PSEPVE) polymer, and the remaining is water. Based on the amount of PEDOT-PSSA and P-(TFE-PSEPVE), acid equivalent ratio of P-(TFE-PSEPVE) to PSSA is 0.18. The mixture was subjected to sonication for 24 minutes continuously using a Branson Model 450 Sonifier* having power set at #4. The glass jug was immersed in ice water contained in a tray to remove heat produced from intense cavitation during the entire period of sonication. The mixture formed a smooth, stable dispersion without any sign of sedimentation. The pH of the dispersion was measured to be 2.0 using a pH meter (model 63) from Jenco Electronics, Ltd (San Diego, Calif.).

Films from the dispersion for electrical resistance measurement were prepared by having a small drop of each dispersion on a 3″×1″ microscope slide. The liquid was spread to cover ⅔ area of the slide placed on a hot plate set at ˜180° C. in air for drying first. The hot plate was increased to 200° C. for baking in air for 5 minutes. The slide containing a dry film was removed from the hot plate and the film was trimmed to a long strip with a razor blade. Width of the strip ranged from 0.2 cm to 0.7 cm and the length was about 3 cm. The thin strip of film was further baked at 210° C. for 10 minutes. Detail of electrical resistance measurement was described in the general procedure. The baked films were tested for electrical resistance as described in the general procedure. Conductivity of six film samples at room temperature was measured to be 218.3 S/cm, 212.0 S/cm, 208.0 S/cm, 207.8 S/cm, 209.1 S/cm, and 205.2 S/cm

Films from the dispersion for work-function measurement were prepared by placing one drop of the dispersion on the center of a 30 mm×30 mm glass/indium/tin semiconductive oxide (ITO) substrate. The film was baked in air 150° C. for 5 minutes. Detail of the measurement was described in the general procedure. Work function was determined to be 5.47 eV. The work function is much higher than the work function of Baytron-P® HCV4, which is smaller than 5.0 eV.

The aqueous dispersion of PEDOT-PSSA/Nafion®/CNT dispersion prepared above one year ago, which provides films having high conductivity and high work-function, was used for incorporation of a semiconductive oxide. The semiconductive oxide is zinc antimonate. It has high refractive index and should enhance refractive index of PEDOT-PSSA which is usually in the range of 1.5 at 460 nm wavelength. Celnax* CX-Z641M, which is a methanol sol of zinc antimonate, purchased from Nissan Chemical America Corporation in Houston, Tex., was used for addition to the aqueous PEDOT-PSSA/Nafion®/CNT dispersion prepared above. 2.7525 g PEDOT-PSSA/Nafion®/CNT dispersion was added with 0.2346 g Celnax* CX-Z641M, which contains 60.2% (w/w) zinc antimonate in methanol. The mixture formed a smooth, stable dispersion in light of the presence of Nafion®, CNT, and ethylene glycol. The final composite dispersion contains 4.7 w % zinc antimonate, 8.75 w % EG, and 1.1 w PEDOT-PSSA/Nafion®/CNT. The mixture contains 4.72 w. % zinc antimonate and 1.11 w % PEDOT-PSSA/Nafion®/CNT. The acid equivalent ratio of Nafion® polymer to PSSA remains at 0.18, which keeps the work function unchanged. Films from the composite dispersion for electrical resistance measurement were prepared in the manner as above. They were baked at 160° C. for 30 nmiutes in air. Conductivity of two film samples was measured to be 168.9 S/cm, and 104.7 S/cm. The conductivity is similar to those without the zinc antimonate. However, having the high weight ratio of zinc antimonate relative to PEDOT-Nafion®/CNT provides high refractive index of resulting solid films.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination.

The use of numerical values in the various ranges specified herein is stated as approximations as though the minimum and maximum values within the stated ranges were both being preceded by the word “about.” In this manner slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

What is claimed is:

1. An aqueous dispersion comprising:
(i) at least one electrically conductive polymer doped with a non-fluorinated polymeric acid;
(ii) at least one fluorinated acid polymer;
(iii) at least one high-boiling polar solvent, and
(iv) nanoparticles of at least one semiconductive metal oxide.

2. The dispersion of claim 1, wherein the electrically conductive polymer is selected from the group consisting of polythiophenes, poly(selenophenes), poly(tellurophenes), polypyrroles, polyanilines, polycyclic aromatic polymers, copolymers thereof, and combinations thereof.

3. The dispersion of claim 2, wherein the electrically conductive polymer is selected from the group consisting of a polyaniline, polythiophene, a polypyrrole, a polymeric fused polycyclic heteroaromatic, copolymers thereof, and combinations thereof.

4. The dispersion of claim 3, wherein the electrically conductive polymer is selected from the group consisting of unsubstituted polyaniline, poly(3,4-ethylenedioxythiophene), unsubstituted polypyrrole, poly(thieno(2,3-b)thiophene), poly(thieno(3,2-b)thiophene), and poly(thieno(3,4-b)thiophene).

5. The dispersion of claim 1, wherein fluorinated acid polymer is a highly-fluorinated acid polymer.

6. The dispersion of claim 5, wherein the highly-fluorinated acid polymer is at least 95% fluorinated.

7. The dispersion of claim 1, wherein the highly-fluorinated acid polymer is selected from a sulfonic acid, a sulfonimide, and a perfluoroolefin having perfluoro-ether-sulfonic acid chains.

8. The dispersion of claim 1, wherein the highly-fluorinated acid polymer is selected from the group consisting of a copolymer of 1,1-difluoroethylene and 2-(1,1-difluoro-2-(trifluoromethyl)allyloxy)-1,1,2,2-tetrafluoroethanesulfonic acid, a copolymer of ethylene and 2-(2-(1,2,2-trifluorovinyloxy)-1,1,2,3,3,3-hexafluoropropoxy)-1,1,2,2-tetrafluoroethanesulfonic acid, a copolymer of tetrafluoroethylene and perfluoro(3,6-dioxa-4-methyl-7-octenesulfonic acid), and a copolymer of tetrafluoroethylene and perfluoro(3-oxa-4-pentenesulfonic acid).

9. The dispersion of claim 1 having a pH greater than 2.

10. The dispersion of claim 1, wherein the acid equivalent ratio of the fluorinated acid polymer to the non-fluorinated polymeric acid is less than 1.

11. The dispersion of claim 1, wherein the semiconductive metal oxide is a mixed oxide of at least one metal selected from the group consisting of the Group 2 elements, the Group 11 elements, the Groups 4-6 elements, the Groups 8-10 transition elements, and the Groups 12-15 elements.

12. The dispersion of claim 1, wherein the semiconductive metal oxide is selected from the group consisting of indium-tin-oxide, doped zinc oxides, gallium-indium-tin oxide, zinc-indium-tin oxides, zinc-doped antimony oxides, zinc antimonates, oxygen deficient molybdenum trioxide, vanadium pentoxide, and mixtures thereof.

13. The dispersion of claim 1, further comprising an additive selected from the group consisting of fullerenes, carbon nanotubes, and combinations thereof.

14. A film made from the dispersion of claim 1.

15. The film of claim 14 having a conductivity of at least 100 S/cm.

16. The film of claim 15, having a work function greater than 5.1 eV.

17. The film of claim 15, having a work function greater than 5.4 eV.

18. The film of claim 15, having a refractive index greater than 1.7.

19. An electronic device comprising at least one layer made from the dispersion of claim 1.

20. The device of claim 19, wherein the at least one layer is selected from the group consisting of a buffer layer, an anode, and a cathode selected from the group consisting of a cathode in a tantalum/Ta₂O₅ capacitor, a cathode in an aluminum/Al₂O₃ capactitor, a cathode deposited on a layer consisting of Ta₂O₅, and a cathode deposited on a layer consisting of Al₂O₃.
